(19) United States
(12) Patent Application Publication
(10) Pub. No.: US 2004/0123895 A1
(43) Pub. Date: Jul. 1, 2004

(54) Diffractive structures for the redirection and concentration of optical radiation

(75) Inventors: Michael J. Kardauskas, Billerica, MA (US); Bernhard P. Piwczyk, Dunbarton, NH (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: SunRay Technologies, Inc., Billerica, MA

(21) Appl. No.: 10/691,452

(22) Filed: Oct. 22, 2003

Related U.S. Application Data
(60) Provisional application No. 60/420,490, filed on Oct. 22, 2002.

(51) Int. Cl. H01L 31/00

(52) U.S. Cl. 136/244; 136/246; 136/256; 136/259

(57) ABSTRACT

A diffractive structure for responding to incident radiation includes a substrate having a diffractive surface and a coating layer disposed over the diffractive surface, the coating layer having an index of refraction substantially different from that of the substrate. The diffractive surface comprises a three-dimensional pattern selected to diffract incident radiation with substantial efficiency into one or more diffraction orders other than the first order and to redirect the diffracted radiation from the structure in at least two directions at angles that are greater than a critical angle required for total internal reflection. In application of the diffractive structure to solar cell modules, a diffractive structure disposed in spaces between plural solar cells redirects incident radiation from the area within the spaces onto the solar cells, thus concentrating solar radiation onto the cells.

### RELATED APPLICATION

This application claims the benefit of U.S. Provisional Application No. 60/420,490 filed on Oct. 22, 2002. The entire teachings of the above application are incorporated herein by reference.

### BACKGROUND

It is well known in optical science that light can be redirected by any one of three optical phenomena: reflection, refraction and diffraction. Reflection can be illustrated with a simple mirror where incident light is reflected from a smooth surface at an angle normal to the surface such that the angle of incidence is equal to the angle of the reflected light but of opposite sign. Refraction can be illustrated by a ray of light in air entering another medium such as water or glass having a different refractive index compared to air. The angle of the refracted light is calculated using Snell's law:

n₁ sin θ₁=n₂ sin θ₂

where n is the refractive index of the medium and θ is the angle of incident light or refracted light. Diffraction is illustrated by light incident on a grating. The light is redirected by diffraction according to the equation:

nλ=2 d sin θ

where n is the order of diffraction, d is the periodicity or spacing of the grating and θ is the angle of diffraction. Diffraction and redirection of light in specific directions can be achieved by the use of specific diffraction gratings and holographic optical elements (HOEs) as illustrated by well-known holograms on credit cards and packaging materials. Yet another way of redirecting light, using diffraction, is the use of computer generated diffractive optical elements (DOEs) as described in “Digital Diffractive Optics—An Introduction to Planar Diffractive Optics and Related Technology,” B. Kress and P. Meyrueis, John Wiley & Sons, Ltd., © 2000, the entire contents of which is incorporated herein by reference.

In the field of solar cells, redirection of light using holographic optical elements disposed above the plane of the solar cells, geometric reflection, and refraction have been used to concentrate solar radiation to increase solar energy density at the solar cell surface. Such known approaches have disadvantages in terms of being difficult to fabricate or use, have high material costs, require tracking, have narrow acceptance angles, or provide only low efficiency improvements.

### SUMMARY

The present invention is directed to structures that use diffraction and/or refraction and reflection to redirect radiation incident on a three-dimensional diffraction pattern in particular diffraction modes at angles greater than a critical angle required for total internal reflection. Embodiments of the diffractive structures of the present invention generally provide beam steering or redirection of diffracted radiation.

In accordance with the present invention, a diffractive structure for responding to incident radiation comprises a substrate having a diffractive surface and a coating layer disposed over the diffractive surface, the coating layer having an index of refraction substantially different from that of the substrate. The diffractive surface comprises a three-dimensional pattern selected to diffract incident radiation with substantial efficiency into one or more diffraction orders other than the first order and to redirect the diffracted radiation from the structure in at least two directions at angles that are greater than a selected angle with respect to the surface normal. In an embodiment, the diffracted directions are four orthogonal directions. The diffractive surface can be a diffractive optical element such as a binary diffractive optic, a multilevel diffractive optic, a kinoform or a hologram. The substrate may comprise a plastic film or other suitable material. The coating layer may comprise a metallic layer such as aluminum or silver, or a dielectric coating comprised of either a single, or, preferably multiple, layers. In embodiments employing metallic layers, an insulation layer of silicon oxide, aluminum oxide, magnesium fluoride, polymer, or other electrically non-conductive material may be disposed over the metal coating layer.

In application of the diffractive structure to solar cell modules, a diffractive structure disposed in spaces between plural solar cells redirects incident radiation from the area within the spaces onto the solar cells, thus concentrating solar radiation onto the cells.

Accordingly, a solar cell module comprises a support structure having a planar surface and a plurality of solar cells overlying the planar surface, the cells having front and back surfaces with the back surfaces facing the planar surface, the cells being spaced from one another, with predetermined areas of the planar surface free of solar cells. The solar cell module further includes a transparent cover member overlying and spaced from the solar cells having a top surface disposed toward incident radiation, and a diffractive optical member overlying the predetermined areas of the planar surface. The diffractive member includes a substrate having a diffractive surface and a coating layer disposed over the diffractive surface, the coating layer having an index of refraction sufficiently different from that of the substrate such that a substantial discontinuity in refractive index occurs at the interface between the coating layer and the diffractive surface. The diffractive surface comprises a relief pattern selected to diffract incident radiation with substantial efficiency into one or more diffraction orders other than the first order, such that the diffracted radiation is redirected from the diffractive surface in at least two directions at angles that are greater than the critical angle for total internal reflection, toward the top surface of the transparent cover plate and internally reflected back toward the solar cells. In embodiments of the solar cell module, the diffractive surface is embossed or molded to a depth less than the thickness of the substrate. The solar cells and the diffractive optical member may be encapsulated in a light transmissive polymer material that extends to and is bonded to the cover member and the planar surface of the support structure, with the light transmissive polymer being engaged with and bonded to the diffractive optical member.

With the present approach, much of the incident radiation is redirected from the surface area between the solar cells onto the cells, thus increasing the overall power production from the cells. Other advantages of the present approach include ease of fabrication, low cost of fabrication, ease of use, wide angle of acceptance, no shadowing of the redirected light by features of the diffractive member or light-redirecting element, and avoidance of mechanical tracking to maintain the effectiveness of the light-redirecting element over substantial variations in the angle of incidence of incoming light.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a sectional view of a diffractive structure in accordance with the principles of the present invention.

FIG. 2A illustrates a phase template for a diffractive optical element comprising eight levels.

FIG. 2B illustrates a diffraction plane view for the pattern resulting from the incidence of a single square beam of light onto the diffractive structure of FIG. 2A.

FIGS. 3A-3D are sectional views taken along lines A-A, B-B, C-C, D-D, respectively, of FIG. 2A.

FIG. 4A illustrates a phase template for a diffractive optical element comprising four levels.

FIG. 4B illustrates a diffraction plane view for the pattern resulting from the incidence of a single square beam of light onto the diffractive structure of FIG. 4A.

FIGS. 5A-5D are sectional views taken along lines A-A, B-B, C-C, D-D, respectively, of FIG. 4A.

FIGS. 6A-6H illustrate steps for fabricating the structure of FIG. 4A.

FIG. 7 is a top plan view of a solar module in accordance with the principles of the present invention.

FIG. 8 is a sectional view of the solar module of FIG. 7.

### DETAILED DESCRIPTION

The present invention is based on use of a class of structures in the field of adaptive optics generally referred to as spatial light modulators, diffractive optical elements, or holographic optical elements.

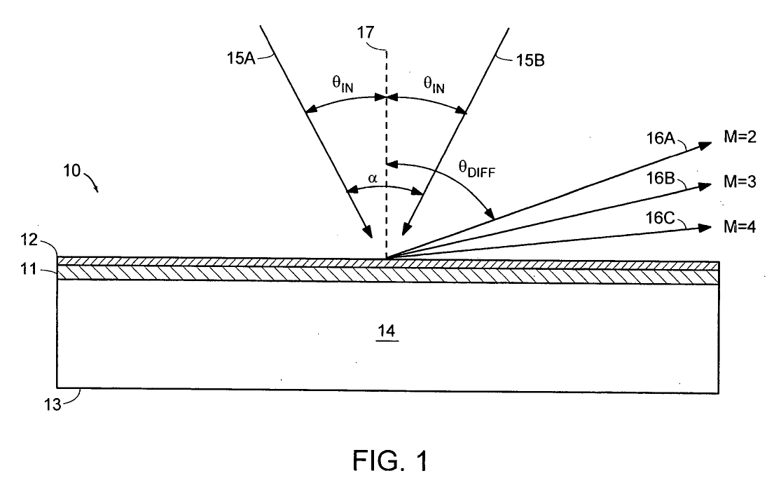

A novel structure for diffracting incident radiation in selected directions is now described. FIG. 1 illustrates an embodiment of a diffractive structure 10 comprising a substrate 14 having a top surface 11 and a bottom surface 13. The top surface 11 has a topographical surface relief pattern, while the bottom surface 13 contains no relief pattern. The substrate can be plastic film or other suitable material. A thin coating layer 12 is disposed over the top surface 11. The coating layer is preferably metallic, such as aluminum or silver. The metallic coating layer may in turn be overcoated with a thin layer of silicon oxide (SiO₂), aluminum oxide (Al₂O₃), magnesium fluoride (MgF), or a polymer to prevent oxidation and/or corrosion, and to provide electrical insulation.

The diffractive structure depicted in FIG. 1 is useful in providing a desired redirection operation with respect to incoming radiation. In particular, for a wide range a of incidence angles θ_{IN} with respect to surface normal 17, the surface relief pattern diffracts incident radiation with substantial efficiency into one or more diffraction orders. The diffracted radiation is redirected from the structure in selected directions at angles that are greater than a selected angle with respect to the surface normal. For example, the incident plane waves 15A, 15B are redirected at second order diffraction mode indicated by plane wave 16A at angle θ_{DIFF}. The surface relief pattern may also diffract the incident radiation at third and fourth orders as shown for plane waves 16B and 16C, respectively, or at still higher orders, depending on the configuration of the kinoform.

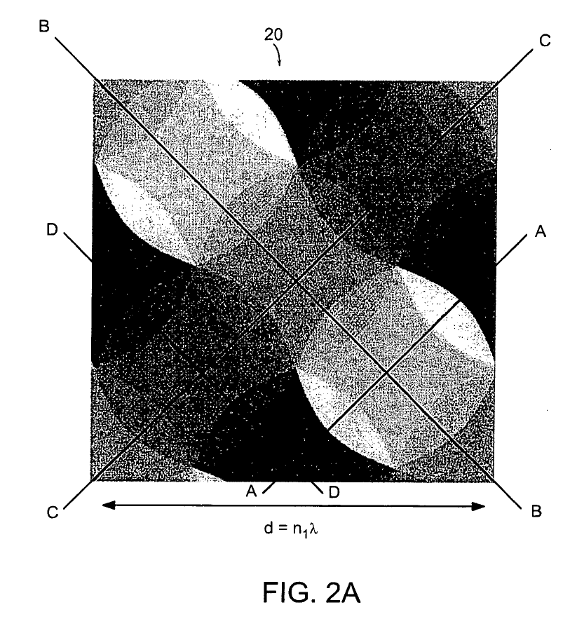

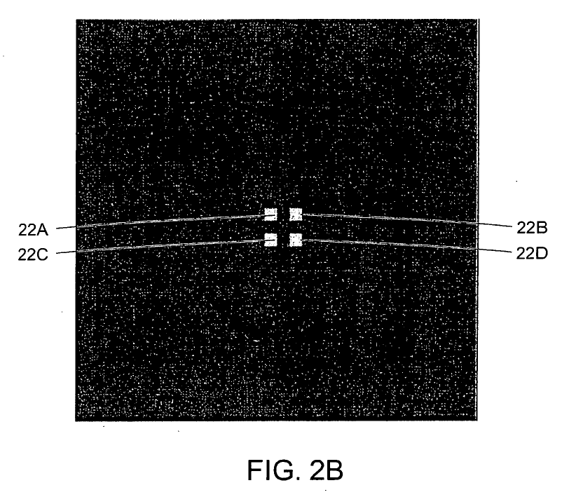

An exemplary surface relief pattern is shown in FIG. 2A. The particular pattern shown is a phase template 20 selected to redirect incident radiation into four second order symmetric diffraction modes and to eliminate redirection of incident radiation of the first order. A diffraction plane view resulting from incidence of a single square beam of light onto the pattern of FIG. 2A is illustrated in FIG. 2B. Four second order modes 22A, 22B, 22C, 22D are shown. The first order is eliminated by cancellation or destructive interference.

In general, a diffractive optical element (DOE) is a component that modifies wavefronts by segmenting and redirecting the segments through the use of interference and phase control. A kinoform is a holographic optical element (HOE) or DOE which has phase-controlling surfaces. A binary optic is a simple DOE that features only two phase-controlling surfaces, which introduce either a 0 or ¼ phase difference to the incident wavefront. When there are N masks, a multilevel binary optic or MLPR DOE can be generated, usually resulting in 2^{N} phase levels. In particular, a multilevel DOE is formed from multiple layers of material of differing thicknesses, such that the layers are combined in various combinations to produce more levels than there are layers. For example, by depositing layers a, b, and c, which are all of different thicknesses, then there can be distinct levels corresponding to 0 (no deposited material), a, b, and c, and also a+b, a+c, b+c, and a+b+c. Thus, depositing N=3 layers can produce 2³ or 8 levels.

The phase template 20 shown in FIG. 2A contains two unit cells, one unbroken in the center of the image and one broken up into 45/90 degree triangles at the four corners of the image. The unit cell is of length d=2λ where λ is the shortest design wavelength of interest. In embodiments, the diffractive pattern comprises repeating unit cell structures that may have lateral dimensions of between 400 nanometers and 4000 nanometers.

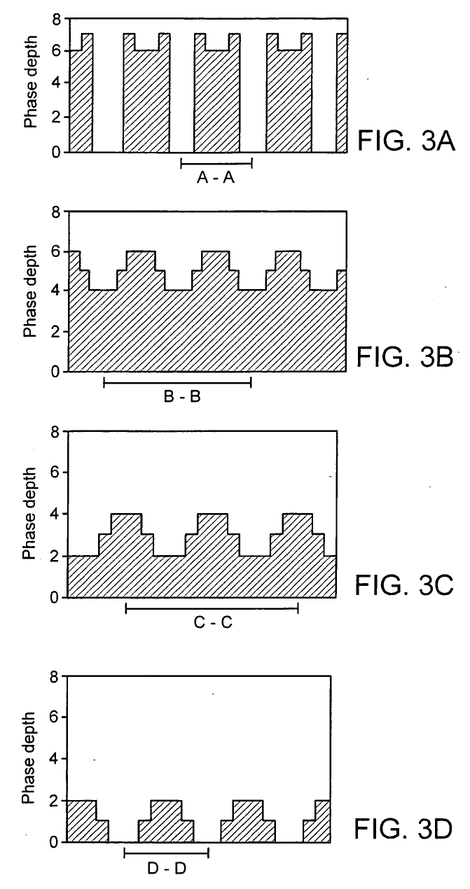

The phase template can be understood as a DOE that has eight equal phase levels of π/8 each and can be generated using three masks, as described further herein. Profiles of the phase depths taken along lines A-A, B-B, C-C, and D-D are illustrated in FIGS. 3A-3D, respectively. For example, the profile taken along line A-A includes transitions from 0 to 7, 7 to 6, 6 to 7, and 7 to 0 phase depth, as shown in FIG. 3A. Cells that adjoin the cell structure shown in FIG. 2A continue with this phase profile. Likewise, the profile taken along line B-B includes a repeating pattern of phase depth transitions from 4 to 5, 5 to 6, 6 to 5, and 5 to 4 (FIG. 3B). The profile taken along line C-C repeats a pattern of phase transitions from 4 to 3, 3 to 2, 2 to 3, and 3 to 4 (FIG. 3C). The profile taken along line D-D has a repeating pattern of transitions from 0 to 1, 1 to 2,2 to 1, and 1 to 0 (FIG. 3D).

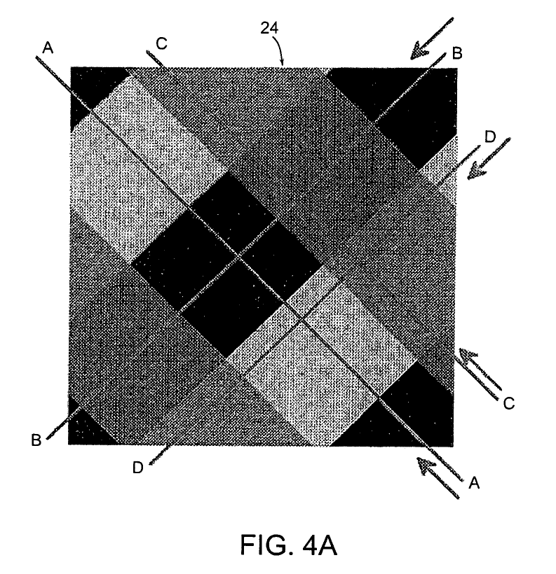

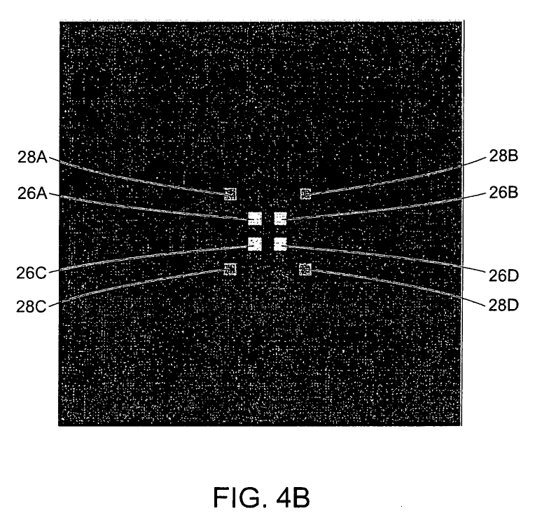

Another exemplary surface relief pattern is shown in FIG. 4A. The particular pattern shown is a four level phase template 24 generated using two masks, with phase levels of π/2. The phase template 24 also redirects incident radiation into four second order symmetric diffraction modes and eliminates redirection of incident radiation of the first order. A diffraction plane view resulting from incidence of a single square beam of light onto the pattern of FIG. 4A is illustrated in FIG. 4B. Four second order modes 26A, 26B, 26C, 26D are shown. In addition, the diffraction from the pattern of FIG. 4A results in third order modes 28A, 28B, 28C, 28D.

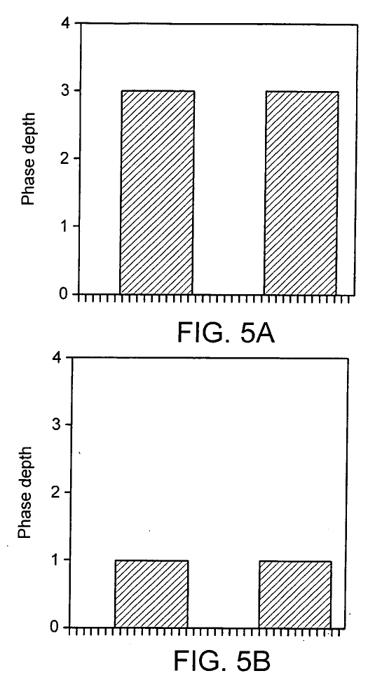

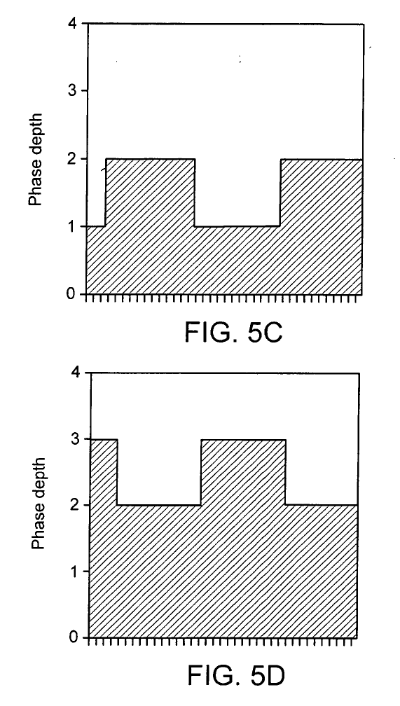

Profiles of the phase depths of the pattern of FIG. 4A taken along lines A-A, B-B, C-C, and D-D are illustrated in FIGS. 5A-5D, respectively. For example, the profile taken along line A-A includes transitions from 0 to 3, 3 to 0, 0 to 3, and 3 to 0 phase depth, as shown in FIG. 5A. Cells that adjoin the cell structure shown in FIG. 4A continue with this phase profile. Likewise, the profile taken along line B-B includes a repeating pattern of phase depth transitions from 0 to 1, 1 to 0, 0 to 1, and 1 to 0 (FIG. 5B). The profile taken along line C-C repeats a pattern of phase transitions from 1 to 2, 2 to 1, and 1 to 2 (FIG. 5C). The profile taken along line D-D has a repeating pattern of transitions from 3 to 2, 2 to 3, and 3 to 2 (FIG. 5D).

The exemplary patterns shown in FIGS. 2A and 4A are of the multilevel type. However, it should be understood that DOEs of the kinoform type that can be computed to provide similar redirection results are also contemplated. Those skilled in the art will appreciate that an increase in the number of levels of the DOE can result in a descrease in the number and intensity of the secondary reflections, which can increase the amount of light directed in useful (rather than non-useful) directions. While the patterns described redirect indicident radiation into four symmetric modes, it will be appreciated that redirection of incident radiation into two, three, five, six or more modes can also achieve the desired optical results of the present invention. In some embodiments, the diffracted directions may be, for example, two directions that are 180 degrees apart, six directions at least 20 degrees apart from one another, or eight directions at least 15 degrees apart from one another.

The phase template views (FIGS. 2A, 4A) and the diffraction plane views (FIGS. 2B, 4B) were generated using AMPERES diffractive optics design tool provided by AMP Research, Inc., Lexington, Mass.

There exists a broad range of manufacturing techniques over a large choice of media for the fabrication and replication of the diffractive structures described herein. Microlithographic fabrication technologies include mask patterning using laser-beam writing machines and electron-beam pattern generators, photolithographic transfer, substrate pattern etching, deep exposure lithography, and direct material ablation. Fabrication techniques include conventional mask alignments using simple binary masks, grey-tone masking, direct write methods, and LIGA processes. Replication of the DOE master can be accomplished using any of the conventional replication techniques, including plastic embossing (hot embossing and embossing of a polymer liquid, followed by UV curing) and molding processes. These technologies and techniques are described in detail in the aforementioned “Digital Diffractive Optics—An Introduction to Planar Diffractive Optics and Related Technology,” B. Kress and P. Meyrueis.

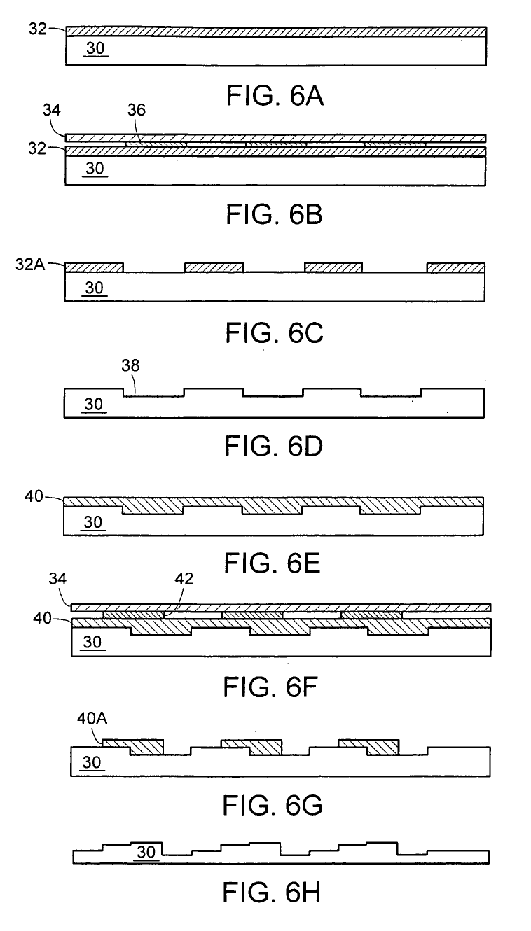

An exemplary method for fabricating a master for a four level diffractive structure of the type shown in FIG. 4A using conventional semiconductor processes is now described with reference to FIGS. 6A-6H. The process starts (FIG. 6A) with a material blank 30 such as a flat plate of high quality quartz or silicon. The blank 30 is coated with a suitable photoresist 32 capable of the required resolution and able to withstand ion milling. Ion milling is a process in which ions (usually Ar) are accelerated so that they impinge on the target substrate with sufficient energy to cause atoms of the target material to be dislodged so that the target material is eroded or “etched”. An alternative method is known as “reactive ion etching”.

The photoresist 32 is exposed (FIG. 6B) using a chrome mask or photomask 34 that carries the required image 36 of the first level required to produce the desired diffractive pattern. Exposure can be performed using common semiconductor fabrication exposure equipment such as wafer steppers or step and scan systems available from ASM, Ultratech, Cannon and others. The image required for mask generation can be computed by diffractive optical element generating software obtainable from various commercial sources (e.g., Code V from Optical Research Associates, Pasdena, Calif.; Zemax from Zemax Development Corporation, San Diego, Calif.; or CAD/CAM design tools from Diffractive Solutions, Neubourg, France) and can be generated using standard chrome photomask making technology for semiconductor circuit fabrication employing commercial mask generating equipment such as MEBES or CORE 2000 marketed by Applied Materials, Inc. In most cases it may be necessary to convert the DOE design output data into a format needed for driving a given mask generation system. FIG. 6B shows a contact printing process which can also be performed by wafer stepper technology.

A standard chemical developer having the desired characteristics needed to develop the chosen photoresist is used to produce a relief pattern 32A as shown in FIG. 6C. The resist relief pattern is transferred into the substrate by ion milling that can be performed by equipment commercially available from VEECO Corporation, for instance. Note that the resist functions as a mask to shield the resist-covered areas from impinging ions. The areas 38 (FIG. 6D) not covered by the resist are eroded or etched by a flood ion beam and the resist is also eroded at the same time but not at the same rate. The erosion rate of the substrate material is generally slower than that of the resist. Etching can be performed to any depth as long as the resist is not completely eroded or etched away. For very deep etching the resist thickness needs to be commensurate with the desired depth required. Shallow ion milling or etching can also be performed but any residual resist needs to be removed chemically afterwards.

To produce the next diffractive pattern level, the substrate 30 is coated with a second layer of photoresist 40 (FIG. 6E). A second resist exposure step (FIG. 6F) with mask 34 carrying image 42 follows. The photoresist is exposed and results in the second resist pattern. The second pattern is precisely aligned with respect to the first exposure. The photoresist is developed with the resulting relief pattern 40A illustrated in FIG. 6G. Ion milling follows and results in the four level structure illustrated in FIG. 6H. The above-described process can be repeated using an increased number of mask levels in order to improve performance criteria, such as efficiency and brightness. Note that the use of two masks results in four levels, three masks produce eight levels, etc.

The master produced by the above-described processes can be used to fabricate a “shim” by plating a layer of nickel on top of the master using either an electrolytic or an electroless process and then removing the nickel replica. The fabricated shim, which is a negative of the master, is then used to generate a stepped and repeated pattern in a larger plate of softer material by stamping or embossing. The plate is then used to produce a shim of the desired size, again by nickel plating. This larger shim can then be put onto a drum that may then be employed to emboss the diffractive pattern onto large rolls of polyethylene terephthalate (PET), polycarbonate, acrylic, or any other suitable film in volume production. Alternatively, the larger shim may be applied to a flat press, which is then used to emboss the diffractive pattern onto flat sheets of the above-named materials.

Those skilled in the art will appreciate that the diffractive structure can be formed as a surface hologram having the desired diffractive properties. Other techniques for forming a diffractive structure include using dot matrix technology, electron beam lithography, or an optical pattern generator.

Having described the features of a diffractive structure that in operation can redirect incident radiation at selected angles, an exemplary application of the structure is now described for use in improving the efficiency of photovoltaic (solar) modules.

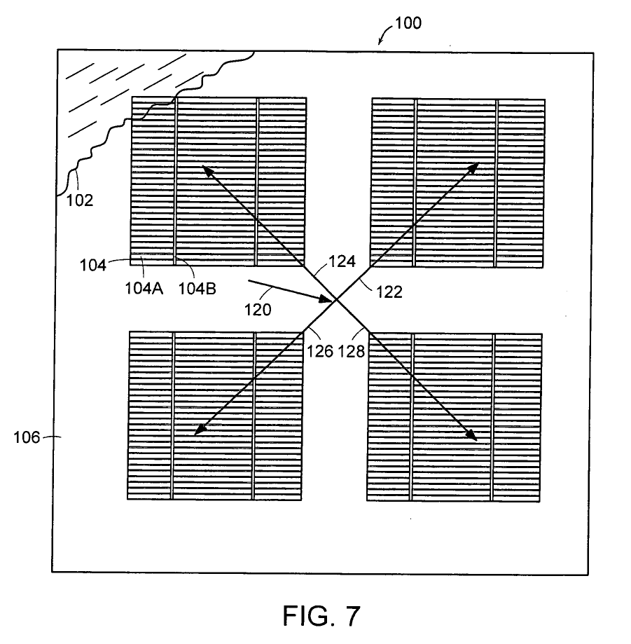

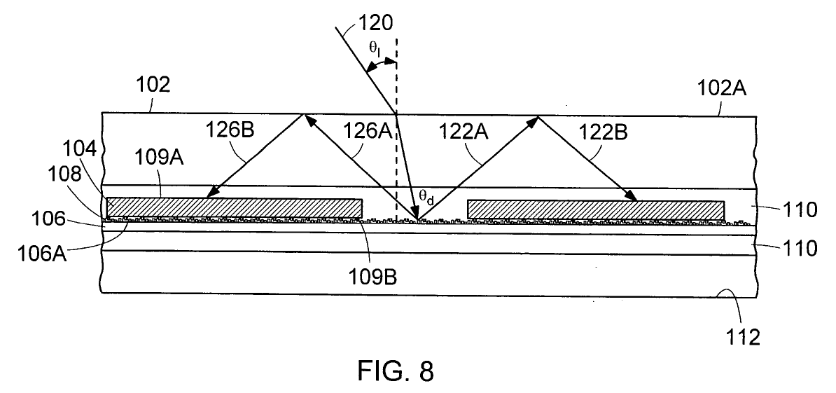

FIGS. 7 and 8 are top plan and cross-sectional views, respectively, that illustrate an embodiment of a solar cell module 100 that incorporates a diffractive structure of the present invention. The solar cell module 100 includes a plurality of rectangular solar cells 104 having respective front and back surfaces 109A, 109B. The type of solar cells used in the module may vary and may comprise, for example, silicon solar cells. Each solar cell has on its front surface 109A a grid array of narrow, elongate parallel fingers 104A interconnected by one or more bus bars 104B. The solar cells are arranged in parallel rows and columns, and are electrically interconnected in a series, parallel or series/parallel configuration, according to the voltage and current requirements of the electrical system into which the module is to be installed.

Overlying the cells is a stiff or rigid, planar light-transmissive and electrically non-conducting cover member 102 in sheet form that also functions as part of the cell support structure. Cover member 102 has a thickness in the range of about ⅛″ to about ⅜″, preferably at least about 3/16″, and has an index of refraction between about 1.4 and 1.6. By way of example, cover member 102 may be made of glass or a suitable plastic such as a polycarbonate or an acrylic polymer. The module 100 also includes a back protector member in the form of a sheet or plate 112 that may be made of various stiff or flexible materials, e.g., glass, plastic sheet or plastic sheet reinforced with glass fibers.

Disposed below the back surface 109B of solar cells 104 is a diffractive optical member 106 comprising a substrate 106A that has a diffractive topographical relief pattern with a thin metallic coating layer on its top surface 108. The pattern can be of the type described above with respect to FIGS. 2A and 4A. The substrate 106A is made of a plastic film material which may be of either the thermoplastic or thermosetting type, on which additional layers, such as of an embossed UV-cured coating, may be applied, and which may be transparent, translucent or opaque. The diffractive optical member 106 is fabricated in accordance with the principles described above for redirecting incident radiation at selected angles. The coating layer is selected to have an index of refraction that is substantially different from that of the substrate, such as, by way of example, metals such as aluminum or silver. The metallic coating layer may in turn be overcoated with a thin layer of silicon oxide (SiO₂), aluminum oxide (Al₂O₃), magnesium fluoride (MgF), or a polymer to prevent oxidation and/or corrosion, and to provide electrical insulation. In other embodiments, the diffractive optical member 106 can be disposed such that the diffractive pattern and coating layer are on the bottom surface facing away from the solar cells, rather than the top surface, so as to avoid any possibility of the metal film short-circuiting the cells. In such embodiments, the substrate 106A is substantially transparent and is selected to have an index of refraction that closely matches the index of refraction of the cover member 102.

As illustrated in FIG. 7, the diffractive optical member 106 extends across the spaces between adjacent cells and also any spaces bordering the array of cells. Note that in other embodiments the diffractive optical member 106 can be disposed substantially co-planar with the solar cells.

Interposed between back sheet 112 and transparent cover member 102 and surrounding the cells 104 and the diffractive optical member 106 is an encapsulant 110 made of suitable light-transparent and electrically non-conducting material, such as ethylene vinyl acetate copolymer (known as “EVA”) or an ionomer. The index of refraction of the encapsulant 110 is selected to closely match that of the cover member 102 and that of the substrate 106A.

The refractive index of the polymeric encapsulant is in the range of 1.4 to 1.6 depending on the specific chemical formulation. The substrate 106A of the diffractive optical member 106 is made from a suitable polymer material meeting a variety of other required physical parameters (e.g., resistance to UV radiation, resistance to moisture, strong adhesion to encapsulant, etc.) which has a refractive index in the same general range of the encapsulant. If the substrate 106A is brought in optical contact with the encapsulant and the diffractive indexes of both materials are the same or approximately the same, the optical property of the diffractive surface 108 would be nullified since the surface topography would be “filled in” by the encapsulant, thus making the diffractive surface essentially ineffective to incident radiation.

This problem is overcome by coating the surface pattern 108 with a thin layer of material such as a metal (aluminum or silver are preferred). A thin layer of about 200 Angstroms (0.02 microns) is sufficient and does not change the properties of the diffractive optical member substantially. This metal layer provides a discontinuity in the refractive index or a large index mismatch at the metal/polymer encapsulant interface so that the diffractive optical member continues to function optically. Alternatively a multiplayer optical coating having reflective properties over a broad portion of the solar spectrum can be used instead of a metallic coating. A multilayer optical coating, however, is generally more expensive than a single reflective metallic coating.

In operation, as illustrated in FIGS. 7 and 8, incident radiation 120 impinges on the diffractive optical member 106 between and around the cells in the module at an incident angle θ₁. The surface relief pattern 108 diffracts the incident radiation with substantial efficiency into four higher order symmetric diffraction modes with no diffracted radiation of the first order. The plane waves 122, 124, 126, 128 indicate the four symmetric diffraction modes. The diffracted radiation is redirected from the diffractive structure 106 in selected directions at angles that are greater than the minimum angle, θᵢ, with respect to the surface normal, that results in total internal reflection at the interface between the transparent cover member 102 and the air above it. The size of this angle can be calculated as:

sin θᵢ=n₂/n₁,

where n₂ is the index of refraction of air and n₁ is the index of refraction of the cover member 102, and for n₂=1 and n₁=1.5, then θᵢ is about 42 degrees.

For a pattern selected of the type shown in FIG. 2A, the features of the pattern can be understood as follows. Let the length of a side of the unit cell be Λ. The wave vector of the diffraction modes at second order makes an angle θ with respect to the surface normal given by

$$tan θ = \frac{2 ( \frac{λ}{Λ} )}{\sqrt{{n}^{2} - 4 {( \frac{λ}{Λ} )}^{2}}} ,$$

where n 1.5. Thus, if we take

Λ=2λ,

then θ=θᵢ, λ is the wavelength and is preferably selected towards the smaller end of the band, since, for a given Λ, longer wavelengths will correspond to larger diffraction angles. For design wavelengths in the range of solar radiation, it is expected that the sum of the diffraction efficiencies for the four modes is greater than about 80%.

The operation shown in FIG. 8 for plane waves 122 and 126 indicates diffracted radiation plane wave 122A at angle θ_{D}>θᵢ is totally reflected back as plane wave 122B to the solar cell 104.

In this manner, substantially all of the incident radiation that is incident on the diffractive surface 108 disposed between the solar cells 104 is redirected by diffraction at the surface 108 and by reflection at the top cover surface 102A onto the solar cells. Thus, power production from the solar cells is increased above the level that such cells would normally produce if the radiation impinging on spaces between the cells were not available.

Since the area in the solar module between the cells is much less costly to produce than the area covered by the solar cells, the difference being the cost of the solar cells, substantial cost savings are possible in the production of solar generated electrical power using the present approach. Actual tests have demonstrated a power output increase of about 12% with 10 cm square cells spaced 2.5 cm apart. Calculations show that changes in the design of the diffractive surface, combined with a further increase in the spacing between the cells, may increase this to 100% or more.

While the distance traveled by a redirected light beam parallel to the surface of the solar module differs as a function of the wavelength of the impinging light when this redirection is accomplished through diffraction, an effect that does not occur in designs employing specular or diffuse reflection, this does not detract from the usefulness of the diffractive method, and, in fact, can allow for collection of part of the solar spectrum from portions of the land area between solar cells that are too distant from any solar cell for the entire spectrum to be collected. This is an advantage not shared by designs relying on either specular or diffuse reflection.

The use of diffraction for the present application permits a very wide angle of acceptance; that is, incident radiation is diffracted with relatively high optical efficiency over wide variations in the angle of the incident light with respect to the diffractive member, and shadowing of the redirected light by geometrical elements essential to the design of the light-redirecting element, particularly at high angles of incidence with respect to the surface normal, as encountered with reflective surfaces relying on specular or diffuse reflection, is essentially avoided. Such shadowing is defined as the interception by a geometric feature of the reflecting surface of light that has previously been redirected in the desired direction by another element of the reflecting surface, such that the light no longer travels in the desired direction. It will be appreciated that such an effect occurs in designs relying on specular or diffuse reflection to a greater extent as the angle of incident light with respect to the normal to the plane of the light-redirecting element increases. This effect limits the effective angle with respect to the normal to the plane of the light-redirecting element at which a specular or diffuse reflector can efficiently redirect light, and this, in turn, limits the land area from which such a reflector can efficiently collect radiation for the purpose of redirecting it to a solar cell. Because diffractive designs do not suffer from the shadowing effect, they can, in principle, collect light from larger land areas within a solar module than can designs relying on specular or diffuse reflection, producing greater economic benefit. As an additional benefit, much of the light which does not intercept a solar cell after being first redirected by the diffractive element and then reflected from the interface between the cover member and the overlying air, and which then strikes the diffractive element at a second location, will again be redirected by the diffracting element in a useful direction, so that it eventually strikes a solar cell in the solar cell array. Because of the shadowing effect in designs relying on specular or diffuse reflection, those designs generally redirect very little light in useful directions after a first reflection from the interface between the cover member and the overlying air.

An embodiment of the diffractive optical member 106 can be produced in several steps. First, the film 106A that serves as the substrate is manufactured as a sheet having smooth upper and lower surfaces. The sheet may then be wound onto a roll for subsequent processing, or it may be passed directly to subsequent processing stages. The subsequent processing comprises first embossing or patterning the film with a master so as to form a diffractive optical surface, and then coating the diffractive surface with metal or a multi-layer dielectric layer.

The embossing or patterning of the film can be accomplished by passing the film between a pinch roller and an embossing roller, the pinch roller having a smooth cylindrical surface and the embossing roller having a negative of the desired optical pattern on its cylindrical surface. The film is processed so that as it passes between the two rollers the surface is shaped by the pattern on the embossing roller. After formation of the diffractive pattern, the plastic film may be subjected to a metallization process such as a conventional vapor deposition or sputtering process.

As noted, the diffractive optical member 106 is disposed so that it occupies the spaces (“land areas”) between cells in a module. Because of the diffractive properties of the diffractive surface pattern, light redirected from one area of the pattern is not blocked by any adjacent area, as can occur in known reflection based systems whenever the incident light arrives from angles other than directly normal to the plane of the reflective element. In addition, a wide angle of acceptance is made possible with the use of the diffractive pattern. Thus, in the present system, light redirected from the pattern and passing into the transparent cover member strikes the front face of the cover member at an angle exceeding the critical angle, with the result that substantially all of the reflected light is reflected internally back toward the solar cells, thereby substantially improving the module's electrical current output.

The diffractive optical member 106 can be assembled into a solar module so as to take advantage of its properties during the module lamination process commonly used to assemble solar modules. In this process, the solar cells become bonded to the transparent cover of the module, and to a bottom protective covering, by means of sheets or films of polymeric material, which are provided between the solar cells and the transparent covering, and also between the solar cells and the rear side protective covering. As the entire assembly is then heated in vacuum, the polymer layers melt, causing all of the components of the solar module to consolidate into a single mass, which becomes solid either as the assembly cools, or after the polymer material, if a thermosetting type, cross-links at an elevated temperature. Alternatively, the polymer may be introduced to the module assembly in the form of a liquid, which is later caused to solidify through the application of heat or UV radiation.

It will be appreciated that for embodiments of the diffractive optical member 106 which comprise materials that can withstand outdoor exposure, the diffractive optical member can itself be used as the bottom protective covering of a solar module, and can be substituted for any other bottom protective covering material during the assembly and lamination process described herein, thereby producing a solar module with the desired properties. Alternately, if the diffractive optical member material is not sufficiently durable to be used as a protective covering itself, it may be inserted into the assembly between the solar cells and the bottom protective covering, with suitable layers of bonding material between it and the solar cells and the bottom protective covering. One method for executing this design is to pre-bond the diffractive optical member to the bottom protective covering material in a process separate from the module assembly itself. The laminate comprising the diffractive optical member bonded to the bottom protective covering material can then be used as the bottom protective covering during conventional module assembly, and confers the benefits of both the rear side protective covering and of the diffractive optical member.

While this invention has been particularly shown and described with references to preferred embodiments thereof, it will be understood by those skilled in the art that various changes in form and details may be made therein without departing from the scope of the invention encompassed by the appended claims.

What is claimed is:

1. A structure for responding to incoming radiation incident thereon, the structure comprising:
a substrate having a diffractive surface;
a coating layer disposed over the diffractive surface, the coating layer having an index of refraction different from that of the substrate;
the diffractive surface comprising a relief pattern selected to diffract incident radiation with substantial efficiency into one or more diffraction orders other than the first order and to redirect the diffracted radiation from the structure in at least two directions at angles that are greater than a selected angle with respect to the surface normal.

2. The structure of claim 1 wherein the diffracted directions are four orthogonal directions.

3. The structure of claim 1 wherein the diffractive surface is a diffractive optical element.

4. The structure of claim 3 wherein the diffractive optical element is a binary diffractive optic.

5. The structure of claim 3 wherein the diffractive optical element is a multilevel diffractive optic.

6. The structure of claim 3 wherein the diffractive optical element is a kinoform.

7. The structure of claim 3 wherein the diffractive optical element is a hologram.

8. The structure of claim 1 wherein the substrate comprises a plastic film.

9. The structure of claim 1 wherein the coating layer comprises a metallic layer.

10. The structure of claim 1 further comprising an insulation layer disposed over the coating layer.

11. The structure of claim 10 wherein the insulation layer comprises silicon oxide (SiO₂).

12. The structure of claim 10 wherein the insulation layer comprises aluminum oxide (Al₂O₃).

13. The structure of claim 10 wherein the insulation layer comprises a polymer.

14. The structure of claim 10 wherein the insulation layer comprises magnesium fluoride (MgF₂).

15. The structure of claim 1 further comprising a transparent cover plate having a top surface disposed toward the incoming radiation and a bottom surface overlying the coating layer wherein incoming radiation incident thereon is propagated toward the diffractive surface and the selected angle is the critical angle for total internal reflection, the diffracted radiation is redirected from the diffractive surface toward the top surface of the transparent cover plate and internally reflected.

16. A solar cell module comprising:
a support structure having a planar surface;
a plurality of solar cells overlying the planar surface, the cells having front and back surfaces with the back surfaces facing the planar surface, the cells being spaced from one another, with predetermined areas of the planar surface free of solar cells;
a transparent cover member overlying and spaced from the solar cells having a top surface disposed toward incident radiation; and
a diffractive optical member overlying the predetermined areas of the planar surface, the diffractive optical member redirecting incident radiation toward the solar cells.

17. The solar cell module of claim 16 wherein the diffractive optical member comprises:
a substrate having a diffractive surface;
a coating layer disposed over the diffractive surface, the coating layer having an index of refraction different from that of the substrate;
the diffractive surface comprising a relief pattern selected to diffract incident radiation with substantial efficiency into one or more diffraction orders other than the first order, the diffracted radiation redirected from the diffractive surface in at least two directions at angles that are greater than the critical angle for total internal reflection, toward the top surface of the transparent cover plate and internally reflected back toward the solar cells.

18. The solar cell module of claim 17 wherein the diffractive surface is embossed or molded to a depth less than the thickness of the substrate.

19. The solar cell module of claim 17 wherein the diffractive pattern comprises repeating unit cell structures having of lateral dimension of between 400 nanometers and 4000 nanometers.

20. The solar cell module of claim 17 wherein the diffractive optical member is disposed so that the diffractive pattern extends to cover the spaces between the solar cells.

21. The solar cell module of claim 17 wherein the diffracted directions are two directions 180 degrees apart.

22. The solar cell module of claim 17 wherein the diffracted directions are four essentially orthogonal directions.

23. The solar cell module of claim 17 wherein the diffracted directions are six directions at least 20 degrees apart from one another.

24. The solar cell module of claim 17 wherein the diffracted directions are eight directions at least 15 degrees apart from one another.

25. The solar cell module of claim 17 wherein the diffractive surface is a diffractive optical element.

26. The solar cell module of claim 25 wherein the diffractive optical element is a binary diffractive optic.

27. The solar cell module of claim 25 wherein the diffractive optical element is a multilevel diffractive optic.

28. The solar cell module of claim 25 wherein the diffractive optical element is a kinoform.

29. The solar cell module of claim 25 wherein the diffractive optical element is a hologram.

30. The solar cell module of claim 17 wherein the substrate comprises a plastic film.

31. The solar cell module of claim 17 wherein the coating layer comprises a metallic layer.

32. The solar cell module of claim 31 wherein the coating layer comprises aluminum or silver.

33. The solar cell module of claim 17 further comprising an insulation layer disposed over the coating layer.

34. The solar cell module of claim 33 wherein the insulation layer comprises silicon oxide (SiO₂).

35. The solar cell module of claim 33 wherein the insulation layer comprises aluminum oxide (Al₂O₃).

36. The solar cell module of claim 33 wherein the insulation layer comprises magnesium fluroride (MgF₂).

37. The solar cell module of claim 31 wherein the coating layer comprises a single dielectric coating.

38. The solar cell module of claim 31 wherein the coating layer comprises a multilayer dielectric coating.

39. The solar cell module of claim 16 wherein the solar cells and the diffractive optical member are encapsulated in a light transmissive polymer material that extends to and is bonded to the cover member and the planar surface of the support structure, with the light transmissive polymer being engaged with and bonded to the diffractive optical member.
